(19) United States
(12) Patent Application Publication
(10) Pub. No.: US 2019/0027548 A1
(43) Pub. Date: Jan. 24, 2019

(54) METHOD FOR MANUFACTURING ARRAY SUBSTRATE OF AMOLED DEVICE

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Chunsheng JIANG, Shenzhen (CN)

(21) Appl. No.: 15/580,985

(22) PCT Filed: Sep. 11, 2017
(86) PCT No.: PCT/CN2017/101164

§ 371 Date: Dec. 8, 2017

(30) Foreign Application Priority Data
Jul. 18, 2017 (CN) 201710586435.2

(51) Int. Cl. H01L 27/32; H01L 27/12; H01L 51/56

(52) U.S. Cl. CPC H01L 27/3276; H01L 27/127; H01L 2227/323; H01L 27/3258; H01L 51/56; H01L 27/3248

(57) ABSTRACT

A method for manufacturing an array substrate of an AMOLED device includes steps of providing a substrate, depositing an amorphous silicon layer on the substrate, patterning the amorphous silicon layer, depositing a photoresist, patterning the photoresist, performing an ion implantation on a thin film transistor, depositing a gate insulating layer and a gate metal layer on the substrate, depositing an interlayer dielectric layer on the substrate, depositing an electrode metal layer on the substrate, depositing an inorganic protective layer on the substrate, and sequentially depositing an electron injecting layer and an electron transporting layer on the substrate.

### FIELD OF THE INVENTION

The present disclosure relates to the field of an active matrix organic light-emitting diode (AMOLED), and more particularly to a method for manufacturing an array substrate of an AMOLED device.

### BACKGROUND OF THE DISCLOSURE

An active matrix organic light-emitting diode is also known as AMOLED. Due to the properties of being light weight, energy conservative, solid state display, high frequency, active lighting, and high contrast, AMOLED screens have a number of unparalleled advantages for liquid crystal displays (LCD).

AMOLED screens are active lighting displays, and display principle thereof is significantly different from LCDs. In addition to the above properties, compared with LCD screens, AMOLED screens also have a number of advantages, such as no viewing angle limitations, light weight, thin, high brightness, high luminous efficiency, richness of luminescent material, easily achievable color display, fast response times, high quality dynamic pictures, wide working temperature ranges, and flexible display.

However, in conventional manufacturing process of the AMOLED devices, thin film transistors have to undergo multiple lithographic operations during manufacturing. Thus, the conventional manufacturing process for the AMOLED device is complicated and the manufacturing cost thereof is high.

Therefore, it is necessary to provide a method for manufacturing an array substrate of an AMOLED device to solve the existing technical problems.

### SUMMARY OF THE INVENTION

An object of the present disclosure is to provide a method for manufacturing an array substrate of an AMOLED device having a relatively simple process and a low cost, for resolving the technical problems of the complicated manufacturing flows and the high manufacturing cost of the conventional method for manufacturing an array substrate of an AMOLED device.

An embodiment of the present disclosure provides a method for manufacturing an array substrate of an AMOLED device, comprising steps of:

providing a substrate, depositing a buffer layer on the substrate, and subsequently depositing an amorphous silicon layer on the substrate;

patterning the amorphous silicon layer to form a region of a thin film transistor of the AMOLED device;

depositing a photoresist on the substrate, and patterning the photoresist based on a source position and a drain position of the thin film transistor of the AMOLED device;

performing an ion implantation on the amorphous silicon layer on the source position and the drain position of the thin film transistor, to form a source and a drain of the thin film transistor;

depositing a gate insulating layer and a gate metal layer on the substrate and patterning the gate metal layer to form a gate of the thin film transistor;

depositing an interlayer dielectric layer on the substrate, and patterning the interlayer dielectric layer to form a source contact through hole, a drain contact through hole, and a gate contact through hole of the thin film transistor;

depositing an electrode metal layer on the substrate and patterning the electrode metal layer based on the source contact through hole, the drain contact through hole, and the gate contact through hole, to form a data line, a scan line, and a pixel electrode on the substrate;

depositing an inorganic protective layer on the substrate, and patterning the inorganic protective layer to expose the pixel electrode; and

sequentially depositing an electron injecting layer and an electron transporting layer on the substrate, wherein the electron injecting layer is in contact with the pixel electrode;

wherein the electron injecting layer and the electron transporting layer cover the entire substrate to form a protective material of the substrate.

In the method for manufacturing an array substrate of an AMOLED device, the buffer layer is a silicon oxide film.

In the method for manufacturing the array substrate of the AMOLED device, the gate metal layer is formed of at least one of neodymium, aluminum, chromium, and copper.

In the method for manufacturing the array substrate of the AMOLED device, the electrode metal layer is a transparent metal layer.

In the method for manufacturing the array substrate of the AMOLED device, the interlayer dielectric layer is a silicon oxide layer or a silicon nitride layer.

In the method for manufacturing the array substrate of the AMOLED device, the substrate is made of at least one of glass, plastic, quartz, and silicon crystal.

In the method for manufacturing the array substrate of the AMOLED device, the step of performing the ion implantation on the amorphous silicon layer on the source position and the drain position of the thin film transistor specifically comprises a step of performing the ion implantation on the amorphous silicon layer on the source position and the drain position of the thin film transistor through a semiconductor ion implantation.

In the method for manufacturing the array substrate of the AMOLED device, the step of patterning the electrode metal layer based on the source contact through hole, the drain contact through hole, and the gate contact through hole to form a data line, a scan line, and a pixel electrode on the substrate specifically comprises a step of forming the data line through the source contact through hole, forming the pixel electrode through the drain contact through hole, and forming the scan line through the gate contact through hole.

An embodiment of the present disclosure provides a method for manufacturing an array substrate of an AMOLED device, comprising steps of:

providing a substrate, and depositing an amorphous silicon layer on the substrate;

patterning the amorphous silicon layer to form a region of a thin film transistor of the AMOLED device;

depositing a photoresist on the substrate, and patterning the photoresist based on a source position and a drain position of the thin film transistor of the AMOLED device;

performing an ion implantation on the amorphous silicon layer on the source position and the drain position of the thin film transistor to form a source and a drain of the thin film transistor;

depositing a gate insulating layer and a gate metal layer on the substrate and patterning the gate metal layer to form a gate of the thin film transistor;

depositing an interlayer dielectric layer on the substrate, and patterning the interlayer dielectric layer to form a source contact through hole, a drain contact through hole, and a gate contact through hole of the thin film transistor;

depositing an electrode metal layer on the substrate and patterning the electrode metal layer based on the source contact through hole, the drain contact through hole, and the gate contact through hole, to form a data line, a scan line, and a pixel electrode on the substrate;

depositing an inorganic protective layer on the substrate, and patterning the inorganic protective layer to expose the pixel electrode; and

sequentially depositing an electron injecting layer and an electron transporting layer on the substrate, wherein the electron injecting layer is in contact with the pixel electrode.

In the method for manufacturing the array substrate of the AMOLED device, the electron injecting layer and the electron transporting layer cover the entire substrate to form a protective material of the substrate.

In the method for manufacturing the array substrate of the AMOLED device, before the step of depositing the amorphous silicon layer on the substrate, the method further comprising a step of depositing a buffer layer on the substrate.

In the method for manufacturing the array substrate of the AMOLED device, the buffer layer is a silicon oxide film.

In the method for manufacturing the array substrate of the AMOLED device, the gate metal layer is formed of at least one of neodymium, aluminum, chromium, and copper.

In the method for manufacturing the array substrate of the AMOLED device, the electrode metal layer is a transparent metal layer.

In the method for manufacturing the array substrate of the AMOLED device, the interlayer dielectric layer is a silicon oxide layer or a silicon nitride layer.

In the method for manufacturing the array substrate of the AMOLED device, the substrate is made of at least one of glass, plastic, quartz, and silicon crystal.

In the method for manufacturing the array substrate of the AMOLED device, the step of performing the ion implantation on the amorphous silicon layer on the source position and the drain position of the thin film transistor specifically comprises a step of performing the ion implantation on the amorphous silicon layer on the source position and the drain position of the thin film transistor through a semiconductor ion implantation.

In the method for manufacturing the array substrate of the AMOLED device, the step of patterning the electrode metal layer based on the source contact through hole, the drain contact through hole, and the gate contact through hole to form a data line, a scan line, and a pixel electrode on the substrate specifically comprises a step of forming the data line through the source contact through hole, forming the pixel electrode through the drain contact through hole, and forming the scan line through the gate contact through hole.

In the method for manufacturing the array substrate of the AMOLED device of the present disclosure, the source and the drain of the thin film transistor are formed by the ion implantation, thereby effectively reducing the number of the lithographic operations for manufacturing the thin film transistor, simplifying the flows of the process for manufacturing the AMOLED device, reducing the manufacturing cost of the AMOLED device, and resolving the technical problems of the complicated manufacturing flows and the high manufacturing cost of the conventional method for manufacturing an array substrate of an AMOLED device.

### BRIEF DESCRIPTION OF THE DRAWINGS

Iii order to more clearly illustrate the embodiments of the present disclosure or the technical solutions in prior arts, the following briefly introduces the accompanying drawings used in the embodiments. Obviously, the drawings in the following description merely show some of the embodiments of the present disclosure. As regards one of ordinary skill in the art, other drawings can be obtained in accordance with these accompanying drawings without making creative efforts.

FIG. 1 is a flowchart of a method for manufacturing an array substrate of an AMOLED device in accordance with a preferred embodiment of the present disclosure.

FIG. 2A to FIG. 2H are schematic views of flows of the method for manufacturing the array substrate of the AMOLED device in accordance with the preferred embodiment of the present disclosure.

### DETAILED DESCRIPTION OF THE PREFERRED EMBODIMENTS

The technical solution in the embodiments of the present disclosure is clearly and fully described as follows in with reference to the accompanying drawings in the embodiments of the present disclosure. Obviously, the described embodiments are merely part of the present disclosure, rather than all embodiments. Based on embodiments in the present disclosure, all other embodiments obtained by a person of ordinary skill in the art without making creative work are within the scope of the present disclosure.

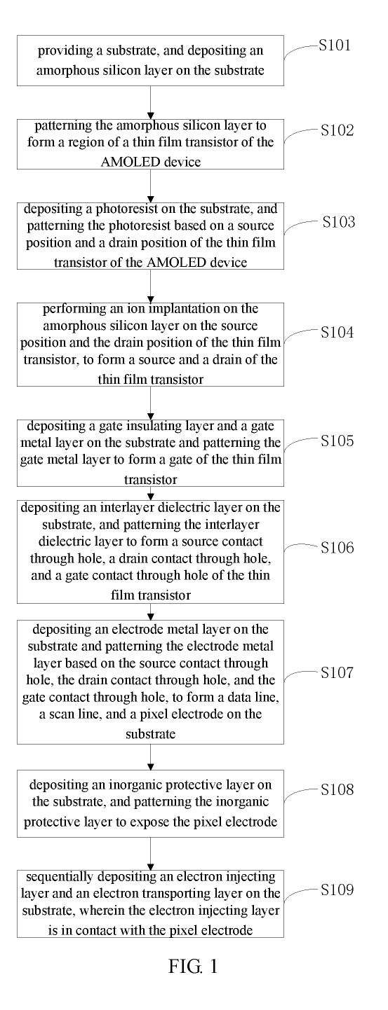

Refer to FIG. 1, which is a flowchart of a method for manufacturing an array substrate of an AMOLED device in accordance with a preferred embodiment of the present disclosure.

A method for manufacturing an OLED display screen integrated with a touch function in the present preferred embodiment includes steps of:

Step S101: providing a substrate, and depositing an amorphous silicon layer on the substrate;

Step S102: patterning the amorphous silicon layer to form a region of a thin film transistor of the AMOLED device;

Step S103: depositing a photoresist on the substrate, and patterning the photoresist based on a source position and a drain position of the thin film transistor of the AMOLED device;

Step S104: performing an ion implantation on the amorphous silicon layer on the source position and the drain position of the thin film transistor, to form a source and a drain of the thin film transistor;

Step S105: depositing a gate insulating layer and a gate metal layer on the substrate and patterning the gate metal layer to form a gate of the thin film transistor;

Step S106: depositing an interlayer dielectric layer on the substrate, and patterning the interlayer dielectric layer to form a source contact through hole, a drain contact through hole, and a gate contact through hole of the thin film transistor;

Step S107: depositing an electrode metal layer on the substrate and patterning the electrode metal layer based on the source contact through hole, the drain contact through hole, and the gate contact through hole, to form a data line, a scan line, and a pixel electrode on the substrate;

Step S108: depositing an inorganic protective layer on the substrate, and patterning the inorganic protective layer to expose the pixel electrode; and

Step S109: sequentially depositing an electron injecting layer and an electron transporting layer on the substrate, wherein the electron injecting layer is in contact with the pixel electrode.

The specific flows of each step in the method for manufacturing the array substrate of the AMOLED device in accordance with the present preferred embodiment are described in detail as follows.

In Step S101, a substrate 11 is provided, and a buffer layer 12 and an amorphous silicon layer 13 are deposited on the substrate 11, wherein the substrate 11 is made of at least one of glass, plastic, quartz, and silicon crystal, and the buffer layer 12 is a silicon oxide film. Then the flow moves to Step S102.

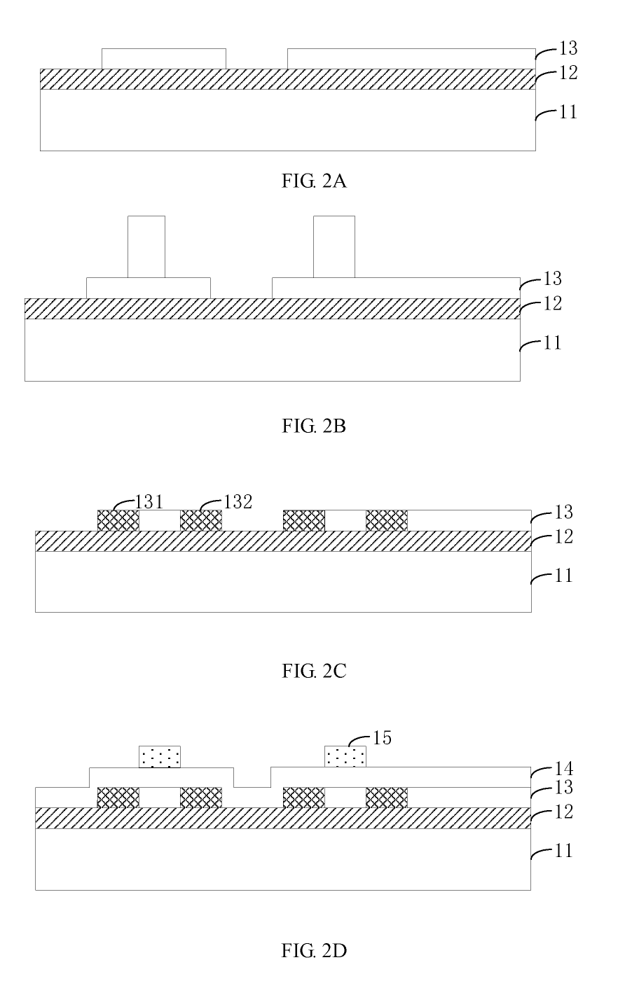

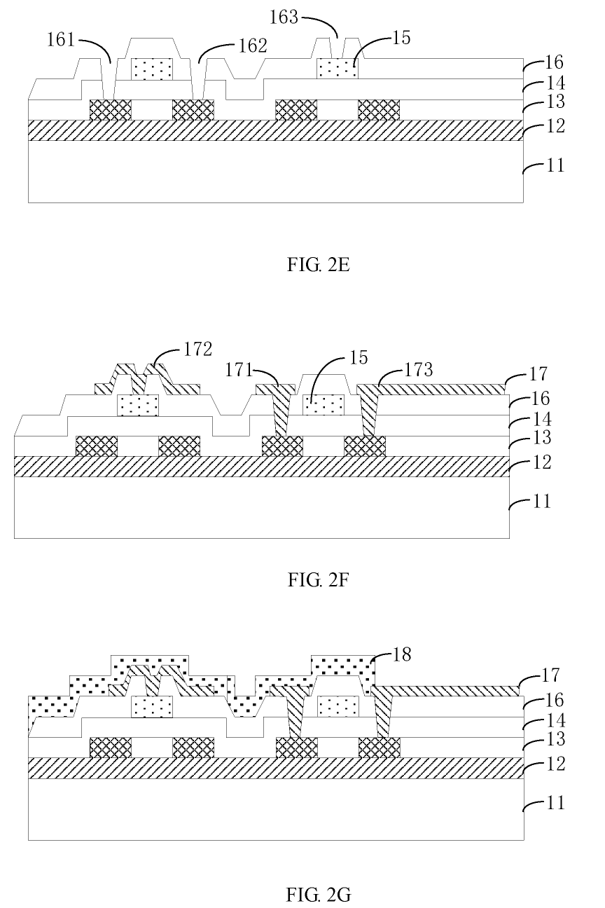

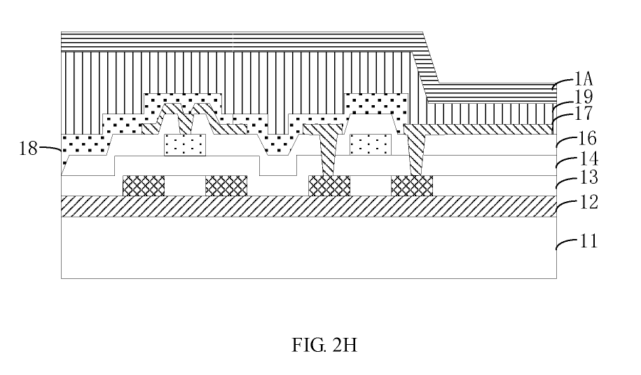

In Step S102, the amorphous silicon layer 13 deposited in step S101 is patterned using a mask, to form the region of the thin film transistor of the AMOLED device, i.e., the amorphous silicon layer 13 is retained in the region of the thin film transistor of the AMOLED device, as specifically shown in FIG. 2A. Then the flow moves to Step S103.

In Step S103, the photoresist is deposited on the substrate 11, and the photoresist is patterned based on the source position and the drain position of the thin film transistor of the AMOLED apparatus, i.e., the photoresist between the source position and the drain position is retained, as specifically shown in FIG. 2B. Then the flow moves to Step S104.

In Step S104, the ion implantation is performed on the amorphous silicon layer on the source position and the drain position of the thin film transistor through a semiconductor ion implantation. Since the blocking photoresist is disposed between the source position and drain position, the ion implantation can be precisely performed on the source position and the drain position of the amorphous silicon layer 13, resulting in the source 131 and the drain 132 of the thin film transistor. Then the photoresist is removed, as specifically shown in FIG. 2C. Then the flow moves to step S105.

In Step S105, the gate insulating layer 14 and the gate metal layer are deposited on the substrate 11, and then the gate metal layer is patterned using a mask, to form the gate 15 of the thin film transistor, as specifically shown in FIG. 2D, wherein the gate metal layer is made of at least one of neodymium, aluminum, chromium, and copper. Then the flow moves to step S106.

In Step S106, the interlayer dielectric layer 16 is deposited on the substrate, and the interlayer dielectric layer 16 is patterned using a mask, to form the source contact through hole 161 of the thin film transistor, the drain contact through hole 162 and a gate contact through hole 163, as specifically shown in FIG. 2E, wherein the interlayer dielectric layer 16 is a silicon oxide layer or a silicon nitride layer. The flow moves to Step S107.

In Step S107, the electrode metal layer 17 is deposited on the substrate 11, which is preferably a transparent metal layer. Then, based on the source contact through hole 161, the drain contact through hole 162 and the gate contact through hole 163, the electrode metal layer 17 is patterned using a mask to form a data line 171, a scan line 172, and a pixel electrode 173 on the substrate. Specifically, the data line 171 is formed through the source contact through hole 161, the pixel electrode 173 is formed through the drain contact through hole 162, and the scan line 172 is formed through the gate contact through hole 163, as shown in FIG. 2F. Then the flow moves to step S108.

In Step S108, the inorganic protective layer 18 is deposited on the substrate 11, and the inorganic protective layer 18 is patterned using a mask to expose the pixel electrode 173, as shown in FIG. 2G. Then the flow moves to Step S109.

In Step S109, the electron injecting layer 19 and the electron transport layer 1A are sequentially deposited on the substrate 11, wherein the electron injecting layer 19 is in contact with the pixel electrode 173. Both the electron injecting layer 19 and the electron transporting layer 1A cover the entire substrate 11, as shown in FIG. 2H. Therefore, the electron injecting layer 19 and the electron transporting layer 1A can be used as the protective material for the substrate 11, and no other protective layer is required.

In this way, the manufacturing process of the method for manufacturing the array substrate of the AMOLED device in the present preferred embodiment is completed.

In the method for manufacturing the array substrate of the AMOLED device of the present disclosure, the source and the drain of the thin film transistor are formed by ion implantation, thereby effectively reducing the number of the lithographic operations for manufacturing the thin film transistor, simplifying the flows of the process for manufacturing the AMOLED device, reducing the manufacturing cost of the AMOLED device, and resolving the technical problems of the complicated manufacturing flows and the high manufacturing cost of the conventional method for manufacturing an array substrate of AMOLED device.

In summary, although the preferable embodiments of the present disclosure have been disclosed above, the embodiments are not intended to limit the present disclosure. A person of ordinary skill in the art, without departing from the spirit and scope of the present disclosure, can make various modifications and variations. Therefore, the scope of the disclosure is defined in the claims.

1. A method for manufacturing an array substrate of an active matrix organic light-emitting diode (AMOLED) device, comprising steps of:
providing a substrate, depositing a buffer layer on the substrate, and depositing an amorphous silicon layer on the buffer layer;
patterning the amorphous silicon layer to form a region of a thin film transistor of the AMOLED device;
depositing a photoresist on the amorphous silicon layer, and patterning the photoresist based on a source position and a drain position of the thin film transistor of the AMOLED device;
performing an ion implantation on the amorphous silicon layer on the source position and the drain position of the thin film transistor, to form a source and a drain of the thin film transistor;
depositing a gate insulating layer and a gate metal layer on the buffer layer, the amorphous silicon layer, the source and the drain and patterning the gate metal layer to form a gate of the thin film transistor;
depositing an interlayer dielectric layer on the gate insulating layer and the gate, and patterning the interlayer dielectric layer to form a source contact through hole, a drain contact through hole, and a gate contact through hole of the thin film transistor;
depositing an electrode metal layer on the interlayer dielectric layer, wherein the source contact through hole, the drain contact through hole, and the gate contact through hole are filled with the electrode metal layer, and patterning the electrode metal layer based on the source contact through hole, the drain contact through hole, and the gate contact through hole, to form a data line, a scan line, and a pixel electrode on the substrate;
depositing an inorganic protective layer on the interlayer dielectric layer, the data line, the scan line, and the pixel electrode, and patterning the inorganic protective layer to expose the pixel electrode; and
sequentially depositing an electron injecting layer and an electron transporting layer on the inorganic protection layer and the pixel electrode, wherein the electron injecting layer is in contact with the pixel electrode;
wherein the electron injecting layer and the electron transporting layer cover the entire substrate to form a protective material of the substrate.

2. The method for manufacturing the array substrate of the active matrix organic light-emitting diode (AMOLED) device as claimed in claim 1, wherein the buffer layer is a silicon oxide film.

3. The method for manufacturing the array substrate of the active matrix organic light-emitting diode (AMOLED) device as claimed in claim 1, wherein the gate metal layer is formed of at least one of neodymium, aluminum, chromium, and copper.

4. The method for manufacturing the array substrate of the active matrix organic light-emitting diode (AMOLED) device as claimed in claim 1, wherein the electrode metal layer is a transparent metal layer.

5. The method for manufacturing the array substrate of the active matrix organic light-emitting diode (AMOLED) device as claimed in claim 1, wherein the interlayer dielectric layer is a silicon oxide layer or a silicon nitride layer.

6. The method for manufacturing the array substrate of the active matrix organic light-emitting diode (AMOLED) device as claimed in claim 1, wherein the substrate is made of at least one of glass, plastic, quartz, and silicon crystal.

7. The method for manufacturing the array substrate of the active matrix organic light-emitting diode (AMOLED) device as claimed in claim 1, wherein the step of performing the ion implantation on the amorphous silicon layer on the source position and the drain position of the thin film transistor specifically comprises a step of:
performing the ion implantation on the amorphous silicon layer on the source position and the drain position of the thin film transistor through a semiconductor ion implantation.

8. The method for manufacturing the array substrate of the active matrix organic light-emitting diode (AMOLED) device as claimed in claim 1, wherein the step of patterning the electrode metal layer based on the source contact through hole, the drain contact through hole, and the gate contact through hole to form a data line, a scan line, and a pixel electrode on the substrate specifically comprises a step of:
forming the data line through the source contact through hole, forming the pixel electrode through the drain contact through hole, and forming the scan line through the gate contact through hole.

9. A method for manufacturing an array substrate of an active matrix organic light-emitting diode (AMOLED) device, comprising steps of:
providing a substrate, and depositing an amorphous silicon layer on the substrate;
patterning the amorphous silicon layer to form a region of a thin film transistor of the AMOLED device;
depositing a photoresist on the amorphous silicon layer, and patterning the photoresist based on a source position and a drain position of the thin film transistor of the AMOLED device;
performing an ion implantation on the amorphous silicon layer on the source position and the drain position of the thin film transistor, to form a source and a drain of the thin film transistor;
depositing a gate insulating layer and a gate metal layer on the buffer layer, the amorphous silicon layer, the source and the drain and patterning the gate metal layer to form a gate of the thin film transistor;
depositing an interlayer dielectric layer on the gate insulating layer and the gate, and patterning the interlayer dielectric layer to form a source contact through hole, a drain contact through hole, and a gate contact through hole of the thin film transistor;
depositing an electrode metal layer on the interlayer dielectric layer, wherein the source contact through hole, the drain contact through hole, and the gate contact through hole are filled with the electrode metal layer, and patterning the electrode metal layer based on the source contact through hole, the drain contact through hole, and the gate contact through hole, to form a data line, a scan line, and a pixel electrode on the substrate;
depositing an inorganic protective layer on the interlayer dielectric layer, the data line, the scan line, and the pixel electrode, and patterning the inorganic protective layer to expose the pixel electrode; and
sequentially depositing an electron injecting layer and an electron transporting layer on the inorganic protection layer and the pixel electrode, wherein the electron injecting layer is in contact with the pixel electrode.

10. The method for manufacturing the array substrate of the active matrix organic light-emitting diode (AMOLED) device as claimed in claim 9, wherein the electron injecting layer and the electron transporting layer cover the entire substrate to form a protective material of the substrate.

11. The method for manufacturing the array substrate of the active matrix organic light-emitting diode (AMOLED) device as claimed in claim 9, before the step of depositing the amorphous silicon layer on the substrate, further comprising a step of depositing a buffer layer on the substrate.

12. The method for manufacturing the array substrate of the active matrix organic light-emitting diode (AMOLED) device as claimed in claim 11, wherein the buffer layer is a silicon oxide film.

13. The method for manufacturing the array substrate of the active matrix organic light-emitting diode (AMOLED) device as claimed in claim 9, wherein the gate metal layer is formed of at least one of neodymium, aluminum, chromium, and copper.

14. The method for manufacturing the array substrate of the active matrix organic light-emitting diode (AMOLED) device as claimed in claim 9, wherein the electrode metal layer is a transparent metal layer.

15. The method for manufacturing the array substrate of the active matrix organic light-emitting diode (AMOLED) device as claimed in claim 9, wherein the interlayer dielectric layer is a silicon oxide layer or a silicon nitride layer.

16. The method for manufacturing the array substrate of the active matrix organic light-emitting diode (AMOLED) device as claimed in claim 9, wherein the substrate is made of at least one of glass, plastic, quartz, and silicon crystal.

17. The method for manufacturing the array substrate of the active matrix organic light-emitting diode (AMOLED) device as claimed in claim 9, wherein the step of performing the ion implantation on the amorphous silicon layer on the source position and the drain position of the thin film transistor specifically comprises a step of:
performing the ion implantation on the amorphous silicon layer at the source position and the drain position of the thin film transistor through a semiconductor ion implantation.

18. The method for manufacturing the array substrate of the active matrix organic light-emitting diode (AMOLED) device as claimed in claim 9, wherein the step of patterning the electrode metal layer based on the source contact through hole, the drain contact through hole, and the gate contact through hole to form a data line, a scan line, and a pixel electrode on the substrate specifically comprises a step of:
forming the data line through the source contact through hole, forming the pixel electrode through the drain contact through hole, and forming the scan line through the gate contact through hole.
